(19) United States
(12) Patent Application Publication
(10) Pub. No.: US 2015/0052745 A1
(43) Pub. Date: Feb. 26, 2015

(54) COMPONENT MOUNTING METHOD

(71) Applicant: Panasonic Corporation, Osaka (JP)

(72) Inventor: Hiroaki KURATA, Yamanashi (JP)

(21) Appl. No.: 14/321,967

(22) Filed: Jul. 2, 2014

(30) Foreign Application Priority Data
Aug. 23, 2013 (JP) 2013-173185

(51) Int. Cl. H05K 3/30

(52) U.S. Cl. CPC H05K 3/30
USPC 29/832

(57) ABSTRACT

In the component mounting method, it is determined whether a component shortage simultaneous occurrence in which predicted component shortage timings belong to the same time zone in component mounting apparatuses and component replenishment is necessary in the same time zone with respect to the component mounting apparatuses is present or not. When the component shortage simultaneous occurrence is determined to be present, the component shortage timing is moved up by a predetermined move-up time in any one of the component mounting apparatuses relating to the component shortage simultaneous occurrence and notified.

### CROSS REFERENCE TO RELATED APPLICATION(S)

The present disclosure relates to the subject matters contained in Japanese Patent Application No. 2013-173185 filed on Aug. 23, 2013, which are incorporated herein by reference in its entirety.

### FIELD

An exemplary embodiment of the present invention relates to a component mounting method in a component mounting system formed by connection of plural component mounting apparatuses that mount an electronic component onto a substrate.

### BACKGROUND

A component mounting system that mounts an electronic component onto a substrate to produce a component-mounted substrate is formed by connection of plural component mounting apparatuses. In each component mounting apparatus, component mounting work for picking up an electronic component from a part feeder provided in a component supply section and for feeding and mounting the picked up electronic component onto the substrate is repeatedly executed. While the component mounting work is being continuously executed, component replenishment work for replenishing new electronic components to the part feeder at a timing when the components are consumed and leads to component shortage is repeatedly executed. If the component replenishment work is not executed in a timely manner, the apparatus should stop due to the component shortage. Thus, in order to execute the component replenishment work at an appropriate timing, for example, a method for notifying an occurrence time of component shortage predicted by a simulation has been used (for example, see Patent Documents 1 and 2).

In a related art example disclosed in Patent Document 1, component shortage is notified in advance according to component consumption information acquired at each sampling time during the component mounting work and a component supply condition. Further, in a related art example disclosed in Patent Document 2, when assigning a worker to execute component replenishment according an advance notification of component shortage, the worker is preferentially assigned, among component mounting machines that form a component mounting system, to a component mounting machine that has the longest cycle time and thus forms a bottleneck in the system.
Patent Document 1 is JP-A-2005-209919. And Patent Document 2 is JP-A-2012-028660.

### SUMMARY

In the related art including the above-mentioned examples disclosed in Patent Documents 1 and 2, there may be a problem in that, with respect to the component mounting system formed by connection of the plural component mounting apparatuses, it may be difficult to execute the component replenishment work in a timely manner without occurrence of the apparatus stoppage due to component shortage. That is, when the component mounting system is continuously operated, the component shortage may simultaneously occur in the plural component mounting apparatuses. In this case, even though the component shortage is notified in advance for each component mounting apparatus as in the above-mentioned related art examples, the appropriate execution of the component replenishment work is not necessarily guaranteed. For example, when the number of the workers that execute the component replenishment work is limited, even though the component mounting apparatus that forms the bottleneck is preferentially set as a work target, the component shortage may occur in a different component mounting apparatus according to situations such as preparation of a component to be replenished, which may cause the apparatus to stop. Further, it is actually difficult to leave an appropriate necessary countermeasure for the simultaneous occurrence of the component shortage to worker's determination. As a result, the frequency of unexpected apparatus stops increases, which leads to a decrease in productivity.

An advantage of some aspects of the embodiment of the invention is to provide a component mounting method capable of preventing an apparatus stoppage due to simultaneous occurrence of component shortage in a component mounting system formed by connection of plural component mounting apparatuses.

According to the embodiment of the invention, there is provided a component mounting method of performing component mounting work of picking up, in a component mounting system formed by connection of a plurality of component mounting apparatuses that mount an electronic component onto a substrate, the electronic component from a part feeder disposed in a component supply section of each component mounting apparatus and of feeding and mounting the picked-up electronic component onto the substrate, the method including: a component mounting process of executing the component mounting work in the plurality of component mounting apparatuses; a component shortage prediction process of predicting a component shortage timing when a component replenishment is necessary due to consumption of the electronic component in each part feeder, during the execution of the component mounting work; and a component replenishment process of executing the component replenishment with respect to the part feeder based on the component shortage timing that is predicted and notified, wherein it is determined whether a component shortage simultaneous occurrence in which the predicted component shortage timings belong to the same time zone in the plurality of component mounting apparatuses and the component replenishment is necessary in the same time zone with respect to the plurality of component mounting apparatuses is present or not, and wherein when the component shortage simultaneous occurrence is determined to be present, the component shortage timing is moved up by a predetermined move-up time in any one of the plurality of component mounting apparatuses relating to the component shortage simultaneous occurrence and notified.

According to the embodiment, during the component mounting work for predicting the component shortage timing when the component replenishment is necessary due to the consumption of the electronic components in each part feeder in the plural component mounting apparatuses and for executing the component replenishment with respect to the part feeder based on the predicted and notified component shortage timing, it is determined whether the component shortage simultaneous occurrence in which the predicted component shortage timings belong to the same time zone in the plural component mounting apparatuses and the component replenishment is necessary in the same time zone with respect to the plural component mounting apparatuses is present or not. Further, if the component shortage simultaneous occurrence is determined to be present, the component shortage timing is moved up by the predetermined move-up time in any one of the plural component mounting apparatuses relating to the component shortage simultaneous occurrence and notified. Thus, it is possible to prevent the apparatus stoppage due to the component shortage simultaneous occurrence in the component mounting system formed by connection of the plural component mounting apparatuses.

### BRIEF DESCRIPTION OF THE DRAWINGS

A general configuration that implements the various features of the invention will be described with reference to the drawings. The drawings and the associated descriptions are provided to illustrate embodiments of the invention and should not limit the scope of the invention.

FIG. 1 is a diagram illustrating a configuration of a component mounting system according to an embodiment of the invention.

FIG. 2 is a plan view of a component mounting apparatus according to the embodiment of the invention.

FIG. 3 is a partial cross-sectional view of the component mounting apparatus according to the embodiment of the invention.

FIG. 4 is a block diagram illustrating a configuration of a control system of the component mounting system according to the embodiment of the invention.

FIGS. 5A and 5B are diagrams illustrating data content of production data in the component mounting system according to the embodiment of the invention.

FIGS. 6A and 6B are diagrams illustrating a component shortage simultaneous occurrence in a component mounting method according to the embodiment of the invention.

FIG. 7 is a diagram illustrating a component shortage simultaneous occurrence avoidance process in the component mounting method according to the embodiment of the invention.

FIG. 8 is a flowchart illustrating a main flow of component mounting work in the component mounting method according to the embodiment of the invention.

FIG. 9 is a flowchart illustrating a component shortage simultaneous occurrence avoidance process in the component mounting method according to the embodiment of the invention.

FIG. 10 is a flowchart illustrating a component shortage simultaneous occurrence avoidance process in the component mounting method according to the embodiment of the invention.

FIG. 11 is a flowchart illustrating a component shortage simultaneous occurrence avoidance process in the component mounting method according to the embodiment of the invention.

FIG. 12 is a flowchart illustrating a component shortage simultaneous occurrence avoidance process in the component mounting method according to the embodiment of the invention.

FIGS. 13A and 13B are diagrams illustrating a component shortage simultaneous occurrence avoidance process in the component mounting method according to the embodiment of the invention.

FIG. 14 is a diagram illustrating a component shortage simultaneous occurrence avoidance process in the component mounting method according to the embodiment of the invention.

### DETAILED DESCRIPTION OF THE EMBODIMENTS

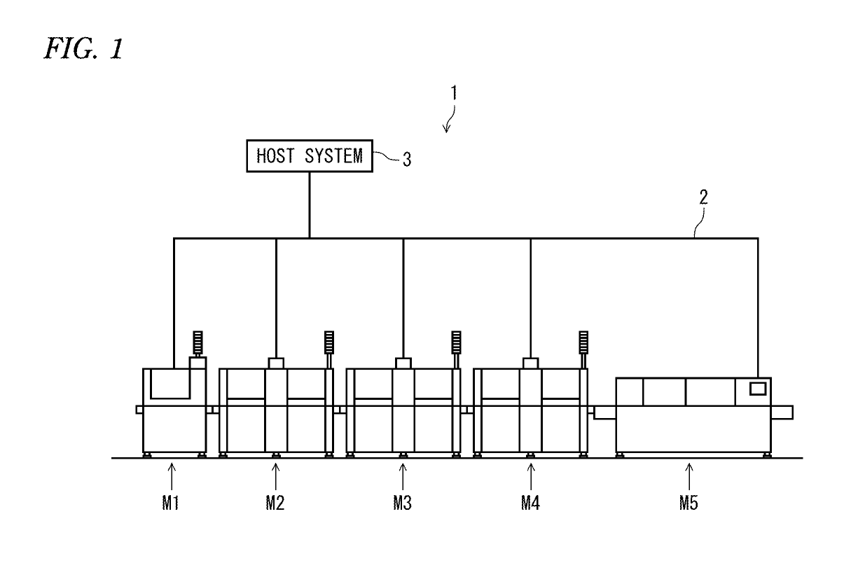

Hereinafter, an exemplary embodiment of the invention will be described with reference to the accompanying drawings. First, a component mounting system will be described with reference to FIG. 1. A component mounting system 1 shown in FIG. 1 has a function of mounting an electronic component onto a substrate to produce a component-mounted substrate, and has a configuration in which a component mounting line formed by connecting respective apparatuses of a printer M1, component mounting apparatuses M2 to M4, and a reflow apparatus M5 is connected by a communication network 2 and all of the apparatuses are controlled by a host system 3. The printer M1 screen-prints paste solder onto an electrode for bonding the electronic component formed on the substrate. Each of the component mounting apparatuses M2 to M4 performs component mounting work of picking up the electronic component from a part feeder disposed in a component supply section and of feeding and mounting the electronic component onto the substrate, using a mounting head. Then, the substrate after the component mounting is sent to the reflow apparatus M5, and then, the electronic component mounted on the substrate is solder-bonded. In this manner, the component-mounted substrate is produced.

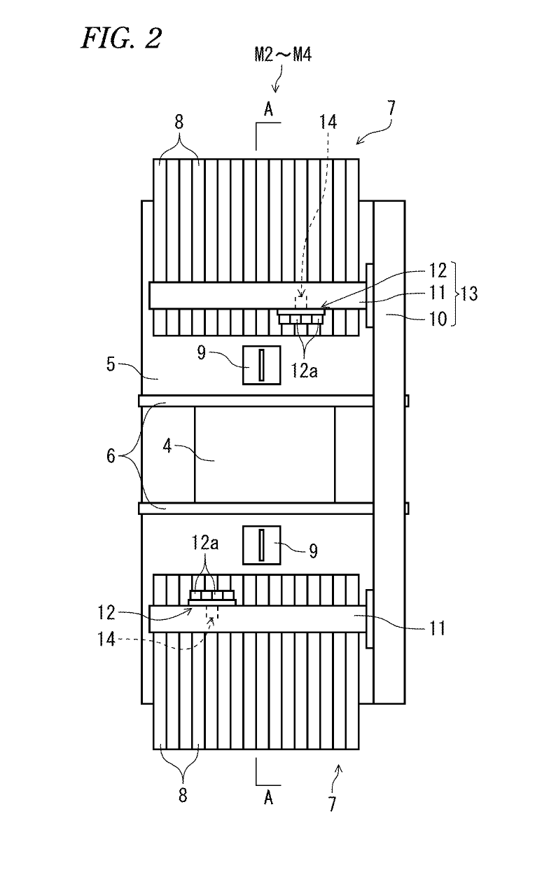

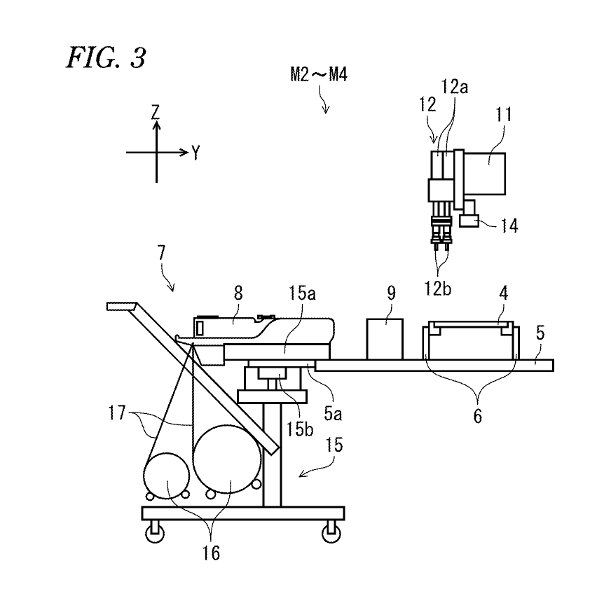

Next, a configuration of the component mounting apparatuses M2 to M4 will be described with reference to FIGS. 2 and 3. FIG. 3 partially shows cross-section A-A in FIG. 2. In FIG. 2, a substrate transport mechanism 6 is disposed at the center of a base 5 in an X direction (substrate transport direction). The substrate transport mechanism 6 transports a substrate 4 carried from an upstream side, and positions and holds the substrate 4 in a predetermined mounting stage for execution of the component mounting work. On both sides of the substrate transport mechanism 6, component supply sections 7 are disposed. Plural tape feeders 8 are provided in parallel in each component supply section 7. The tape feeder 8 pitch-feeds a carrier tape that accommodates an electronic component in a tape feeding direction, to thereby supply the electronic component to a component adsorbing position using the mounting head of a component mounting mechanism to be described below.

In one side end portion of an upper surface of the base 5 in the X direction, a Y-axis moving table 10 provided with a linear drive mechanism is disposed. Further, two X-axis moving tables 11 similarly provided with a linear drive mechanism are coupled to the Y-axis moving table 10 to be movable in the Y direction. Amounting head 12 is mounted to each of the two X-axis moving tables 11 to be movable in the X direction. The mounting head 12 is a multi transfer head provided with plural holding heads 12a. As shown in FIG. 3, an adsorbing nozzle 12b that adsorbs and holds an electronic component and individually moves up and down is mounted to a lower end portion of each holding head 12a.

As the Y-axis moving table 10 and the X-axis moving table 11 are driven, the mounting heads 12 move in the X direction and the Y direction. Thus, each of the two mounting heads 12 picks up the electronic component from the component adsorbing position of the tape feeder 8 disposed in each component supply section 7 using the adsorbing nozzle 12b and feeds and mounts the picked-up electronic component into a mounting point of the substrate 4 positioned in the substrate transport mechanism 6. The Y-axis moving table 10, the X-axis moving table 11, and the mounting heads 12 form a component mounting mechanism 13 that picks up the electronic component by adsorbing and holding the electronic component from the component supply section 7 using the adsorbing nozzle 12b and feeds and mounts the picked-up electronic component onto the substrate 4.

A component recognition camera 9 is disposed between the component supply section 7 and the substrate transport mechanism 6. When the mounting head 12 that picks up the electronic component from the component supply section 7 moves above the component recognition camera 9, the component recognition camera 9 images the electronic component held by the mounting head 12 for recognition. A substrate recognition camera 14 that is disposed on the side of a lower surface of the X-axis moving table 11 and moves integrally with the mounting head 12 is mounted to each mounting head 12. As the mounting head 12 moves, the substrate recognition camera 14 moves above the substrate 4 positioned in the substrate transport mechanism 6, and images the substrate 4 for recognition. In a component mounting operation with respect to the substrate 4 using the mounting head 12, a mounting position correction is performed in consideration of the recognition result of the electronic component using the component recognition camera 9 and the substrate recognition result using the substrate recognition camera 14.

As shown in FIG. 3, a cart 15 in which the plural tape feeders 8 are mounted to a feeder base 15a in advance is set in the component supply section 7. By clamping the feeder base 15a to a fixed base 5a provided in the base 5 using a clamp mechanism 15b, the position of the cart 15 is fixed in the component supply section 7. A supply reel 16 that accommodates a carrier tape 17 that holds the electronic components in a wound state is held in the cart 15. The carrier tape 17 pulled out of the supply reel 16 is pitch-fed to the component adsorbing position related to the adsorbing nozzle 12b by the tape feeder 8. While the above-described component supply is being continuously performed, if component shortage occurs in each tape feeder 8, component replenishment work for exchanging the supply reel 16 where the component shortage occurs into a new unused supply reel 16 is executed.

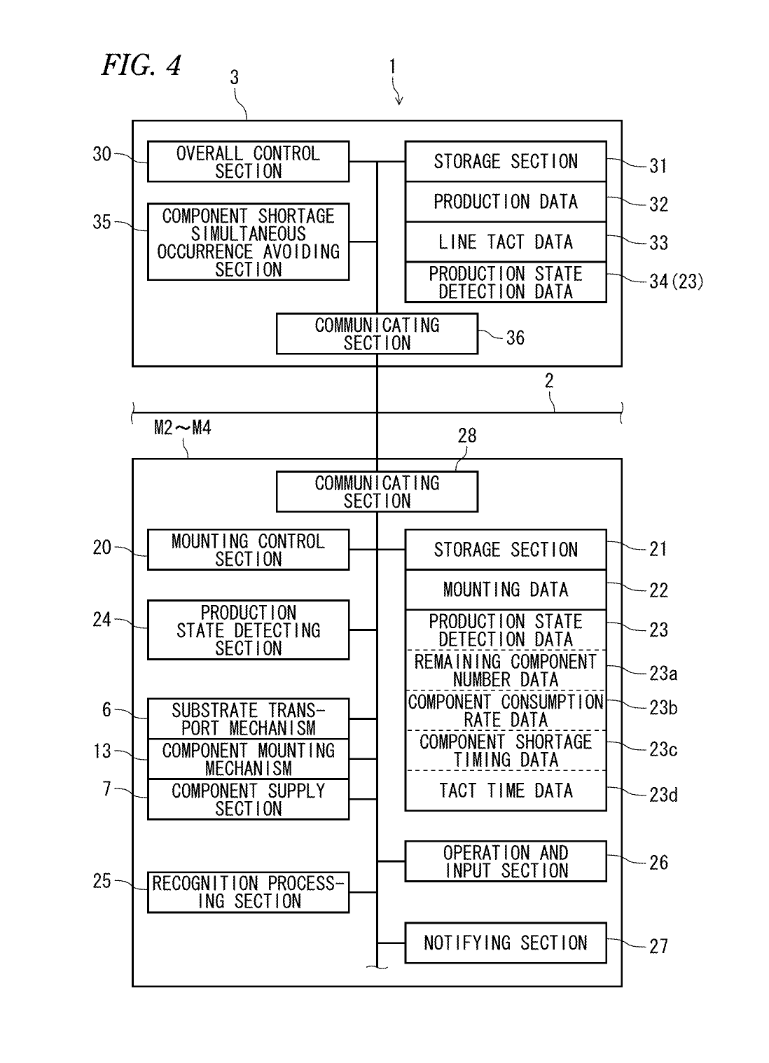

Next, a configuration of a control system of the component mounting system 1 will be described with reference to FIG. 4. Here, only the host system 3 and the component mounting apparatuses M2 to M4 will be described, and the description of the other apparatuses will not be made. In the configuration of the component mounting apparatuses M2 to M4, amounting control section 20 controls respective sections to be described below based on various control processing programs or data stored in a storage section 21 to execute the component mounting work. That is, the mounting control section 20 has an operation control function, and performs the component mounting work for controlling the component supply section 7, the substrate transport mechanism 6, and the component mounting mechanism 13 to mount the electronic component picked up from the tape feeder 8 of the component supply section 7 onto the substrate 4 on which the transport position is determined using the substrate transport mechanism 6. When controlling the component mounting work, mounting data 22 stored in the storage section 21 is referenced.

While the component mounting work is being executed, a process of detecting a production state in the component mounting apparatus is executed by a production state detecting section 24 based on an operation monitoring function of the mounting control section 20. The production state detecting section 24 has a production state detection function such as a component remaining number calculation function, a tact time detection function, a component consumption rate detection function, and a component shortage timing calculation function, and the detection result is stored in the storage section 21 in real time as production state detection data 23 including remaining component number data 23a, component consumption rate data 23b, component shortage timing data 23c, and tact time data 23d.

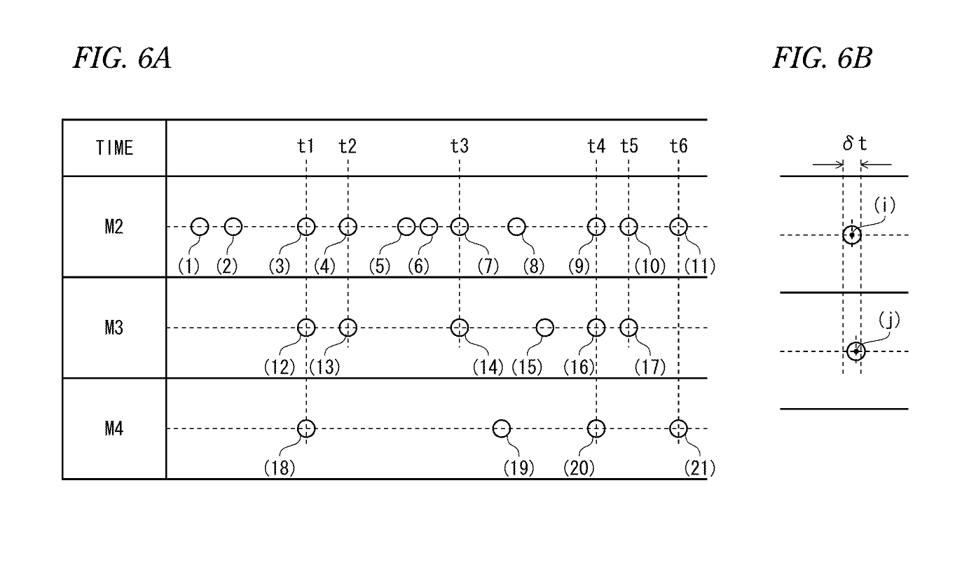

The remaining component number data 23a refers to data indicating the number of remaining components in each tape feeder 8, and the component consumption rate data 23b refers to data indicating a component consumption rate, that is, the number of consumed components per unit time in each tape feeder 8. Further, the component shortage timing data 23c refers to data that is derived from the remaining component number and the component consumption rate to predict a timing when the component shortage occurs in the tape feeder (see FIG. 6A). The tact time data 23d refers to data indicating a necessary work time per unit substrate in the component mounting work of the component mounting apparatus.

The recognition processing section 25 recognizes the imaging results of the component recognition camera 9 and the substrate recognition camera 14. Thus, identification and position detection of the electronic component held by the mounting head 12 are performed, and the position of the substrate 4 held by the substrate transport mechanism 6 is detected. When feeding and mounting the electronic component using the mounting head 12, a position correction of the component mounting point is performed in consideration of these recognition results.

An operation and input section 26 is an input device such as a touch panel switch or a ten key switch provided in an operation panel, through which an input operation for data input or operation command input is performed. A notifying section 27 is notification means such as a display panel or an alarm light, which performs notification for a predetermined item that should be notified to an operator. This notification includes notification of a component shortage timing when the component shortage occurrence is predicted in any tape feeder 8 of the component supply section 7 or a component shortage simultaneous occurrence alarm indicating that the component shortage simultaneously occurs in the plural component mounting apparatuses. Further, these respective sections are connected to the host system 3 through a communicating section 28 that is an interface and the communication network 2, so that signal transmission and reception between the component mounting apparatuses M2 to M4 and the host system 3 is performed.

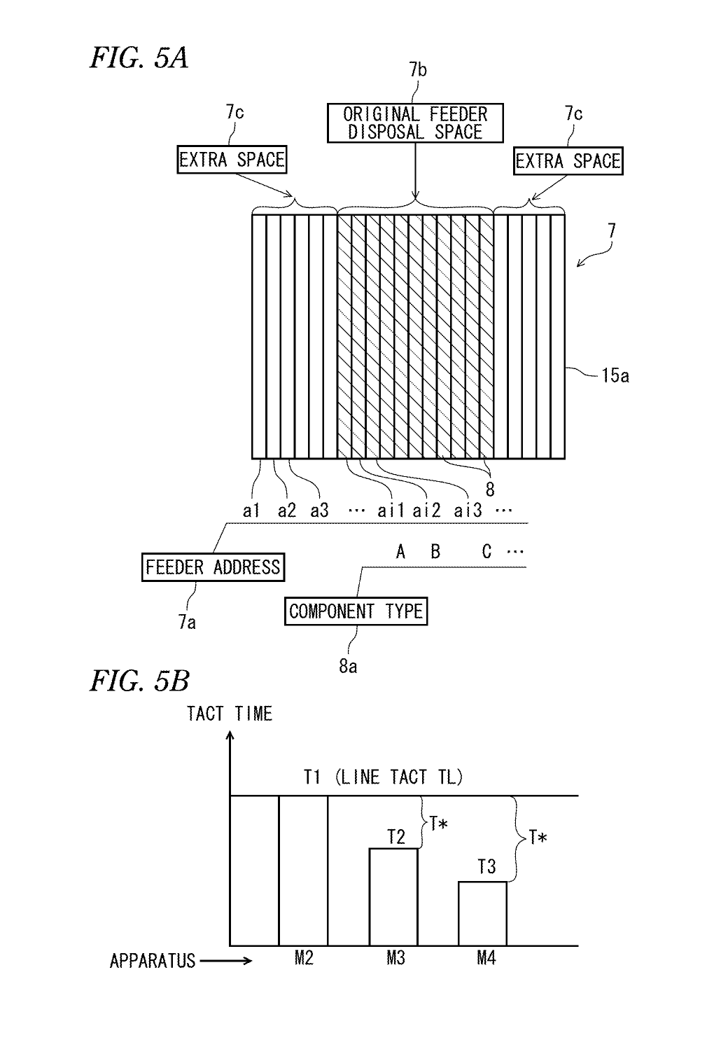

The host system 3 includes an overall control section 30, a storage section 31, a component shortage simultaneous occurrence avoiding section 35, and a communicating section 36. The overall control section 30 manages the respective apparatuses that form the component mounting system 1 based on a processing program or data stored in the storage section 31. In the storage section 31, production data 32, line tact data 33, and production state detection data 34 are stored. The production data 32 refers to data for execution of production work for the component mounting in each component mounting apparatus, that is, the component mounting work, and includes feeder disposal data for regulation of the disposal of the tape feeders 8 in the component supply section 7 of each component mounting apparatus, as shown in FIG. 5A.

A feeder address 7a (a1, a2, a3 . . . ) that specifies the mounting position of the tape feeder 8 in the component supply section 7 is set in the feeder base 15a of the cart 15 set in the component supply section 7. Further, a component type Sa (A, B, C . . . ) indicating the type of the electronic component supplied by the tape feeder 8 allocated to the feeder address 7a is provided corresponding to the feeder address 7a where the tape feeder 8 is disposed based on the feeder disposal data. In the component mounting work, as the feeder address 7a corresponding to the component type 8a to be mounted is designated, the tape feeder 8 that is a component pick-up target is specified.

In the disposal of the tape feeders 8 in the feeder base 15a, the tape feeders 8 are not necessarily allocated to all the feeder addresses 7a. As shown in FIG. 5A, an extra space 7c that does not serve as a disposal target of the tape feeders 8 is present according to the production type, in addition to an original feeder disposal space 7b that is regulated from the beginning by a mounting work optimizing calculation. In the present embodiment, as described later, in order to prevent disturbance of the component replenishment work due to the component shortage simultaneous occurrence of the tape feeder 8 in the plural component mounting apparatuses, the extra space 7c is used as a disposal space for a substitute feeder that is additionally disposed to adjust the component shortage timing.

The line tact data 33 regulates a line tact that is a reference tact time in operation of the mounting line that forms the component mounting system 1, that is, the component mounting apparatuses M2 to M4. As shown in FIG. 5B, respective tact times of the respective apparatuses of the component mounting apparatuses M2 to M4 are T1, T2, and T3, respectively. Here, the tact time T1 corresponding to the component mounting apparatus M2 is the longest. That is, the component mounting apparatus M2 is a bottleneck apparatus that controls the rate of production tact in the component mounting system 1. Accordingly, the tact time T1 of the component mounting apparatus M2 becomes a line tact TL of the component mounting system 1.

In the component mounting apparatuses M3 and M4, the tact times T2 and T3 are set to be shorter than the line tact TL by a spare time T*. In the present embodiment, in order to prevent disturbance of the component replenishment work due to the component shortage simultaneous occurrence of the tape feeder 8 in the plural component mounting apparatuses, a component shortage simultaneous occurrence avoidance process to be described later is performed to adjust the component shortage timing using the spare time T*.

The production state detection data 34 is obtained by storing the production state detection data 23 obtained in the component mounting apparatuses M2 to M4 for each apparatus in real time. The component shortage simultaneous occurrence avoiding section 35 performs a process of selectively executing an operation for avoiding a situation where the predicted component shortage timing simultaneously occurs in the plural component mounting apparatuses, based on the component shortage timing data 23c detected by the production state detecting section 24 of each component mounting apparatus. The communicating section 36 that is the interface performs signal transmission and reception between the host system 3 and the component mounting apparatuses M2 to M4 through the communication network 2.

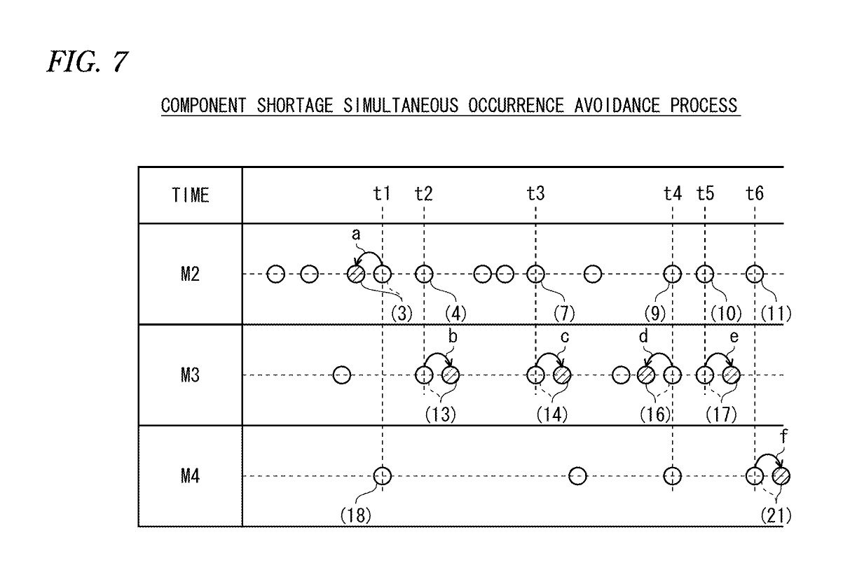

Next, the data content of the component shortage timing data 23c and the function of the component shortage simultaneous occurrence avoiding section 35 will be described with reference to FIGS. 6A, 6B and 7. FIG. 6A shows component shortage timings predicted by a calculation function of the production state detecting section 24 of the component mounting apparatuses M2 to M4. In FIGS. 6A and 6B, 0 marks plotted along a time axis for each of the respective component mounting apparatuses M2, M3, and M4 represent timings when the component shortage occurs in any tape feeder 8 in the component mounting apparatus.

An index (i) given to each O mark in a time series order specifies each component shortage timing. That is, component shortage timings (1) to (11) represent the component shortage that is predicted to occur in the component mounting apparatus M2 in a time series order. Similarly, component shortage timings (12) to (17) and component shortage timings (18) to (21) represent the component shortage that occurs in the component mounting apparatuses M3 and M4 in a time series order.

In the configuration in which the plural component mounting apparatuses are disposed in series as in the component mounting system 1, there is a tendency that a micro component such as a chip component is preferentially mounted and thus the component mounting apparatus that mounts a large component is disposed on a downstream side. Thus, as shown in FIG. 6A, there is a tendency that the component shortage occurs at the highest frequency in the component mounting apparatus M2 positioned in the uppermost stream and the frequency of the component shortage is reduced on a downstream side.

At these component shortage timings (i), two component shortage timings (3) and (18) are predicted to occur at close timings (simultaneous occurrence timing t1), and two component shortage timings (4) and (13) are similarly predicted to occur at close timings (simultaneous occurrence timing t2).

Here, the component shortage simultaneous occurrence represents a situation where the predicted plural component shortage timings (i) and (j) belong to the same time zone defined by a predetermined time width δt in the plural component mounting apparatuses and the component replenishment is necessary at the same time zone with respect to the plural component mounting apparatuses as a target, as shown in FIG. 6B. That is, even though the predicted component shortage timings are not strictly identical to each other on the time axis, in a case where it is determined that the strict distinction is not preferable in view of execution of the component replenishment work, this case is determined as the component shortage simultaneous occurrence.

Similarly, at subsequent simultaneous occurrence timings t3 and t4, two component shortage timings (7) and (14) and three component shortage timings (9), (16), and (20) are predicted to simultaneously occur at close timings, and at simultaneous occurrence timings t5 and t6, two component shortage timings (10) and (17) and component shortage timings (11) and (21) are predicted to simultaneously occur at close timings.

If the above-described component shortage simultaneous occurrence frequently occurs in the component mounting system 1 in which the plural component mounting apparatuses are connected, it is difficult to appropriately handle timely component replenishment work by a limited number of operators, which may cause the apparatus stoppage. Thus, in the present embodiment, in order to avoid the component shortage simultaneous occurrence as much as possible, the process for avoiding the component shortage simultaneous occurrence is selected and executed by the function of the component shortage simultaneous occurrence avoiding section 35.

That is, as shown in FIG. 7, by applying the component shortage simultaneous occurrence avoidance process for the simultaneous occurrence timing t1 to the simultaneous occurrence timing t6, respectively, it is possible to shift any timing among the plural component shortage timings relating to the simultaneous occurrence on the time axis and to remove the component shortage simultaneous occurrence. For example, with respect to the simultaneous occurrence timing t1, by moving up (arrow a) the component shortage timing (3) in the component mounting apparatus M2, it is possible to avoid the component shortage simultaneous occurrence with the component shortage timing (18). Further, with respect to the simultaneous occurrence timings t2, t3, t5, and t6, by respectively postponing (arrows b, c, e, and f) the component shortage timings (13), (14), and (17) in the component mounting apparatuses M3 and the component shortage timing (21) in the component mounting apparatus M4, it is possible to avoid the component shortage simultaneous occurrence with the component shortage timings (4), (7), (10), and (11). Further, with respect to the simultaneous occurrence timing t4, by moving up (arrow d) the component shortage timing (16) in the component mounting apparatus M3, it is possible to avoid the component shortage simultaneous occurrence with the component shortage timing (9).

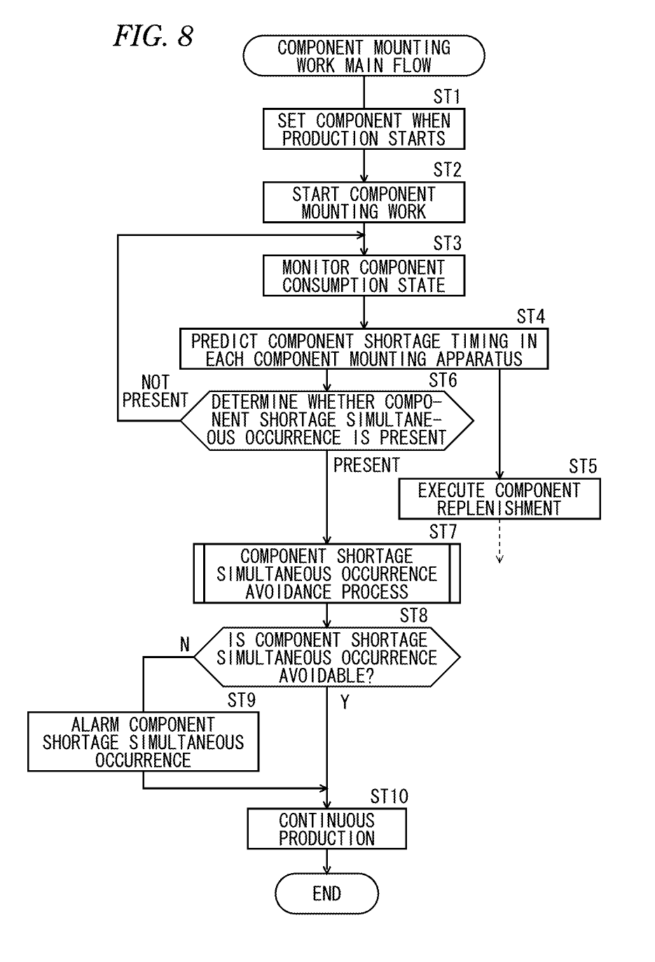

Hereinafter, in the component mounting system 1 having the above-described configuration, a component mounting method for performing the component mounting work executed in the component mounting apparatuses M2 to M4 will be described. Here, the above-described component shortage simultaneous occurrence avoidance process executed during the component mounting work will be described with reference to the flows of FIGS. 8 to 12.

First, a main flow of the component mounting work will be described with reference to FIG. 3. In FIG. 3, when the production starts in the component mounting apparatuses M2 to M4, the setting of the components is executed (step ST1). Then, the component mounting work starts (step ST2). The component mounting work is repeated until the production of a predetermined amount of component-mounted substrates finished. That is, in the component mounting apparatuses M2 to M4, the component mounting operation for picking up the electronic component from the plural tape feeders 8 disposed in the component supply section 7 and for feeding and mounting the picked-up electric component onto the substrate 4 is repeatedly executed. During this operation, monitoring of a component consumption state is continuously executed by the processing function of the production state detecting section 24 (step ST3). The component shortage timing in each component mounting apparatus is predicted by the monitoring of the component consumption state, and is stored as the component shortage timing data 23c (step ST4). The predicted component shortage timing is notified by the notifying section 27, and then, an operator that receives this notification executes the component replenishment work with respect to the tape feeder 8 relating to the notification of the component shortage (step ST5).

That is, the processes shown in the above-described steps include a component mounting process of executing the component mounting work in the plural component mounting apparatuses M2 to M4, a component shortage prediction process of predicting the component shortage timing when the component replenishment is necessary due to the consumption of the electronic component in each tape feeder 8 during the execution of the component mounting work, and a component replenishment process of executing the component replenishment with respect to the corresponding tape feeder 8 based on the predicted and notified component shortage timing.

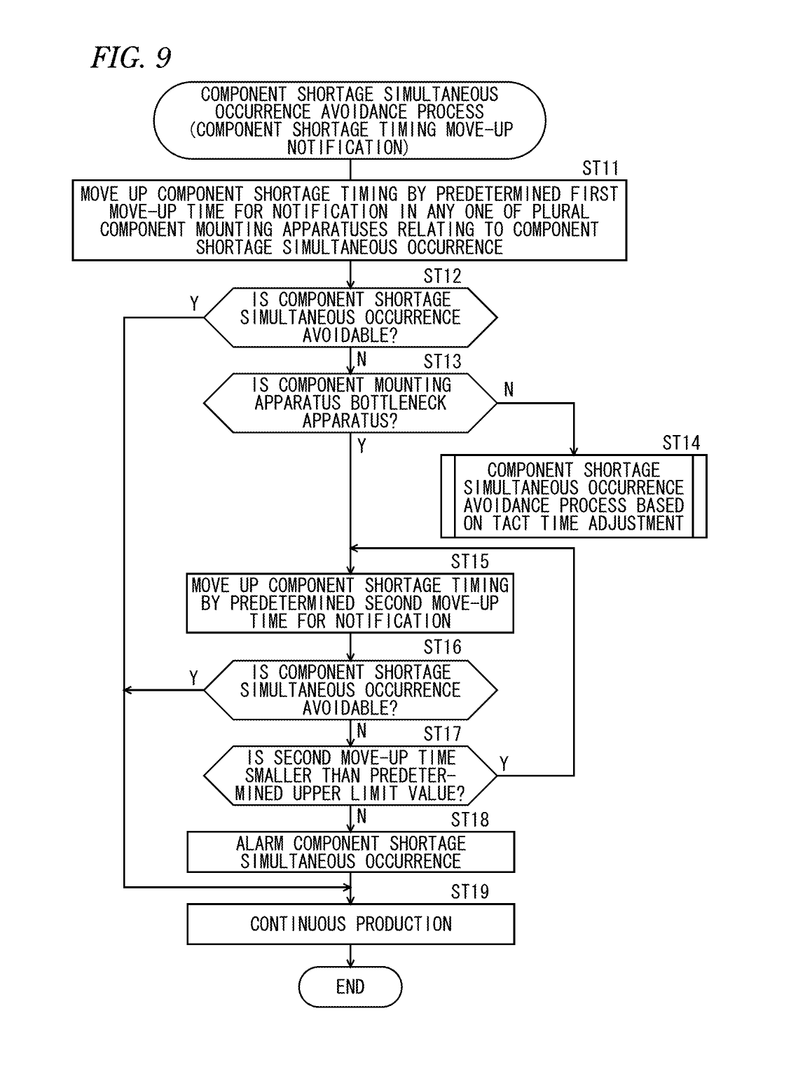

Then, the following process steps are executed by the processing function of the component shortage simultaneous occurrence avoiding section 35 of the host system 3 based on the component shortage timing data 23c indicating the component shortage timing predicted in step ST4. First, it is determined whether the component shortage simultaneous occurrence is present or not between the plural component mounting apparatuses (step ST6). That is, it is determined whether or not the predicted component shortage timings belong to the same time zone in the component mounting apparatuses M2 to M4 and the component replenishment is necessary at the same time zone with respect to the component mounting apparatuses M2 to M4 (step ST6). Here, if it is determined that the component shortage simultaneous occurrence is not present, the procedure returns to step ST3, and then, the monitoring of the component consumption state is continuously executed. Further, if it is determined that the component shortage simultaneous occurrence is present, the component shortage simultaneous occurrence avoidance process to be described in FIG. 9 and thereafter is selectively executed (step ST7).

Then, it is determined whether or not the component shortage simultaneous occurrence is avoidable by the component shortage simultaneous occurrence avoidance process (step ST8). Here, if it is determined that the component shortage simultaneous occurrence is avoidable, the procedure proceeds to a continuous production for continuously executing the component mounting work (step ST10). Further, if it is determined that the component shortage simultaneous occurrence is not avoidable, a component shortage simultaneous occurrence alarm is given (step ST9), and then, the procedure proceeds to the continuous production (step ST10). Then, after a predetermined amount of production is finished, the component mounting work is ended.

Next, details of the component shortage simultaneous occurrence avoidance process executed in step ST7 will be described. First, the component shortage simultaneous occurrence avoidance process based on a component shortage timing move-up notification will be described with reference to FIG. 9. Here, if it is determined in step ST 6 that the component shortage simultaneous occurrence is present, the component shortage timing in any one of the plural component mounting apparatuses relating to the component shortage simultaneous occurrence is moved up by a predetermined first move-up time and notified to avoid the component shortage simultaneous occurrence (step ST11).

In FIG. 7, an example in which the component shortage timing (3) of the component mounting apparatus M2 with respect to the simultaneous occurrence timing t1 is moved up and notified is shown. Here, the first move-up time is appropriately set in consideration of a necessary time for the component replenishment work with respect to one tape feeder 8. Then, under the condition that the notification of the component shortage timing is moved up as described above, it is determined whether the component shortage simultaneous occurrence is avoidable (step ST12). Here, if it is determined that the component shortage simultaneous occurrence is avoidable, the procedure proceeds to a continuous production for continuously executing the component mounting work (step ST19). Then, similar to step ST10 and thereafter in FIG. 8, after a predetermined amount of production is finished, the component mounting work is ended.

Further, if it is determined in step ST 12 that the component shortage simultaneous occurrence is not avoidable, it is determined whether the component mounting apparatus that is an avoidance process target is the bottleneck apparatus having the longest tact time (step ST13). Here, if it is determined that the component mounting apparatus is not the bottleneck apparatus, the procedure proceeds to the component shortage simultaneous occurrence avoidance process based on the tact time adjustment using the spare time T* shown in FIG. 5B (step ST14). Further, if it is determined that the component mounting apparatus is the bottleneck apparatus, since delay of the tact time is not allowed any longer to observe the line tact, the notification of the component shortage timing is moved up by a predetermined second move-up time to avoid the component shortage simultaneous occurrence (step ST15).

Here, the second move-up time is set to be longer than the first move-up time, which is effective in view of the avoidance of the component shortage simultaneous occurrence. However, it is not preferable that the move-up is allowed to be unlimited in view of the original purpose of a preliminary notice of the component shortage timing. Thus, in the present embodiment, an upper limit value is set for the second move-up time.

Then, under the condition that the notification of the component shortage timing is moved up as described above, it is determined whether the component shortage simultaneous occurrence is avoidable (step ST16). Here, if it is determined that the component shortage simultaneous occurrence is avoidable, the procedure proceeds to the continuous production for continuously executing the component mounting work (step ST19). Further, if it is determined in step ST12 that the component shortage simultaneous occurrence is not avoidable, it is determined whether the second move-up time is smaller than the predetermined upper limit value (step ST17). If it is determined that the second move-up time is smaller than the upper limit value, the procedure returns to step ST12, and then, a longer second move-up time is set. Further, if it is determined that the second move-up time in step ST17 exceeds the upper limit value, it is determined that the component shortage simultaneous occurrence is not possible any more. Then, the component shortage simultaneous occurrence alarm is given (step ST18), and then, the procedure proceeds to the continuous production (step ST19). That is, in the component shortage simultaneous occurrence avoidance process shown in FIG. 9, if it is determined that the component shortage simultaneous occurrence is not yet avoidable even if the move-up time exceeds the predetermined upper limit time, the alarm indicating the determination is given.

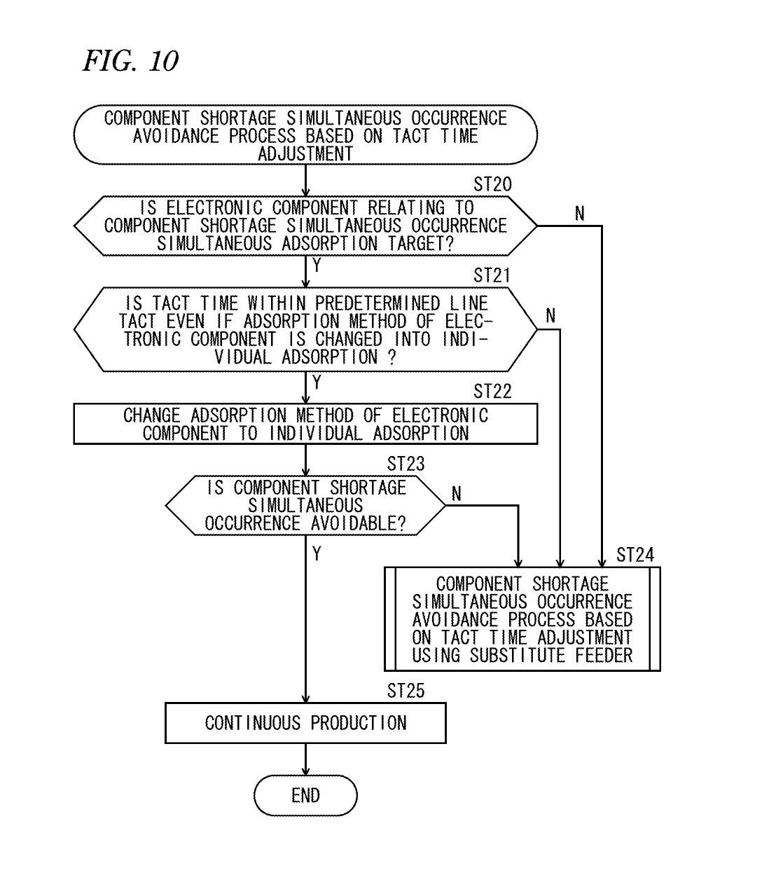

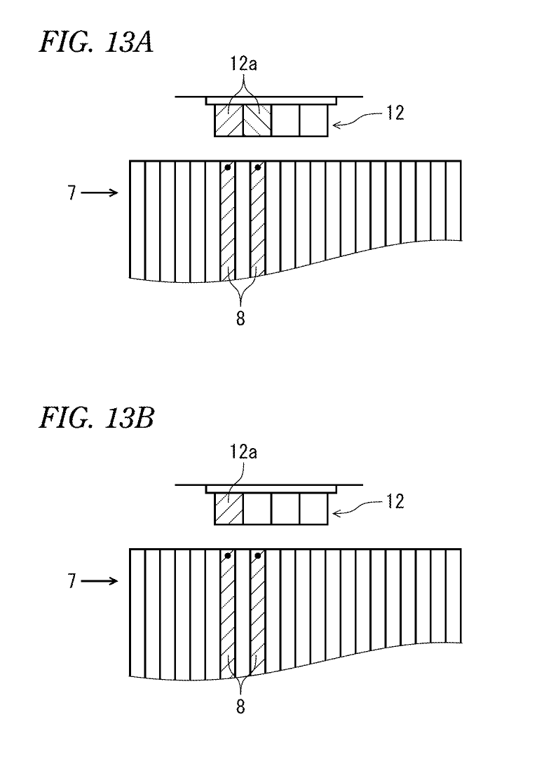

Next, details of the component shortage simultaneous occurrence avoidance process based on the tact time adjustment executed in step ST14 will be described with reference to FIGS. 10, 13A and 13B. This component shortage simultaneous occurrence avoidance process based on the tact time adjustment is applied to a case where the component mounting apparatus that is the avoidance process target is not the bottleneck apparatus and the tact time adjustment using the spare time T* shown in FIG. 5B is allowed.

Here, this component shortage simultaneous occurrence avoidance process is applied to a case where a simultaneous adsorption in which the mounting head 12 adsorbs and holds the electronic components by the plural adsorbing nozzles 12b in a unit mounting turn in which the mounting head 12 reciprocates between the component supply section 7 and the substrate 4 according to the component mounting operation is employed in the component mounting apparatus that is the avoidance process target. That is, this component shortage simultaneous occurrence avoidance process is applied to a case where the simultaneous adsorption in which the plural (here, two) tape feeders 8 of the same component type disposed in the component supply section 7 are disposed with a disposal pitch that is the same as the pitch of the holding heads 12a of the mounting head 12 and two electronic components of the same component type are capable of being picked up by the same adsorbing operation from two tape feeders 8 using these two holding heads 12a is employed, as shown in FIG. 13A.

In FIG. 10, first, it is determined whether the electronic component relating to the component shortage simultaneous occurrence is a simultaneous adsorption target (step ST20), and then, it is determined whether the tact time of the corresponding component mounting apparatus is within the predetermined line tact TL (see FIG. 5B) even if the adsorption method of the electric component is changed to the individual adsorption (step ST21). Here, if it is determined in step ST 20 that the electronic component is not the simultaneous adsorption target, and if it is determined in step ST 21 that the tact time is not within the predetermined line tact TL, the procedure proceeds to the component shortage simultaneous occurrence avoidance process based on the tact time adjustment using the substitute feeder, as a next alternative (step ST24).

Further, if it is determined in step ST 21 that the tact time is within the predetermined line tact TL, the adsorption method of the corresponding electronic component is changed to the individual adsorption (step ST22). That is, as shown in FIG. 13B, among two tape feeders 8 that are component pick-up targets based on the same adsorbing operation in the simultaneous adsorption, the component pick-up from one tape feeder 8 is stopped, and the electronic component is picked up from only the other tape feeder 8. Thus, in the tape feeder 8 that is the component pick-up target based on the individual adsorption, the consumption rate of the electronic component is increased, and thus, the component shortage occurrence timing is moved up. In the example shown in FIG. 7, when it is preferable that the component shortage timing (16) of the component mounting apparatus M3 be moved up (arrow d) with respect to the simultaneous occurrence timing t4, the component shortage simultaneous occurrence avoidance process shown in FIG. 10 is selected.

That is, in the component shortage simultaneous occurrence avoidance process shown in FIG. 10, with respect to the component mounting apparatus other than the bottleneck apparatus having the longest cycle time among the plural component mounting apparatuses, by increasing the consumption rate of the electronic component in the specific tape feeder relating to the component shortage occurrence in the component mounting apparatus, the component shortage simultaneous occurrence avoidance process for avoiding the component shortage simultaneous occurrence is executed.

Specifically, in the component mounting apparatus that is the simultaneous occurrence avoidance process target, when the electronic component relating to the component shortage simultaneous occurrence is the simultaneous adsorption target in execution of the simultaneous adsorption for picking up the plural electronic components of the same component type from the plural tape feeders 8 in the same mounting turn in which the electronic component is picked up from the component supply section 7 and is fed and mounted onto the substrate 4 by the mounting head 12, the simultaneous adsorption is not executed, and the electronic component is continuously picked up from one of the plural tape feeders 8, so that the consumption rate of the electronic component relating to the component shortage occurrence is increased.

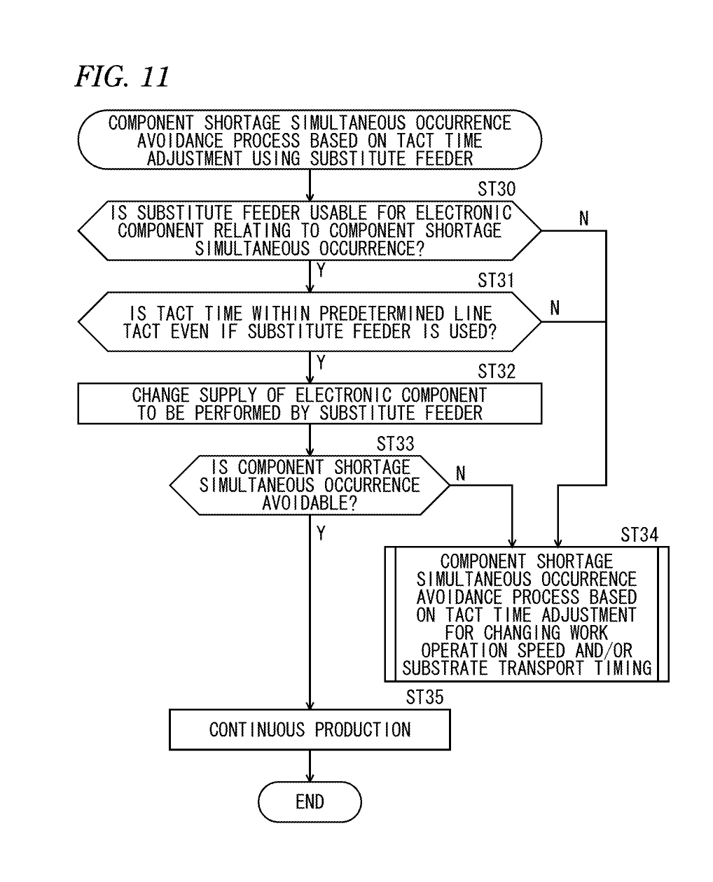

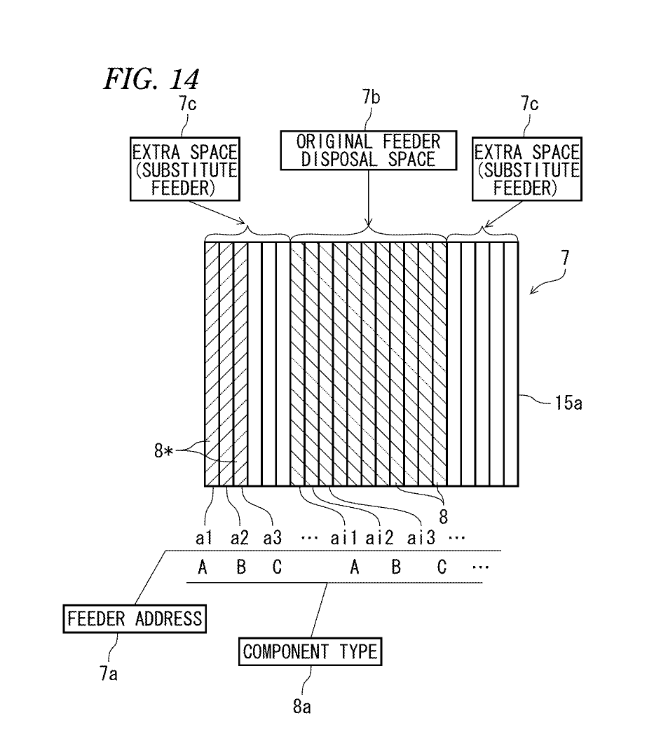

Next, details of the component shortage simultaneous occurrence avoidance process based on the tact time adjustment using the substitute feeder executed in step ST 24 will be described with reference to FIGS. 11 and 14. This component shortage simultaneous occurrence avoidance process based on the tact time adjustment using the substitute feeder is applied to a case where the component mounting apparatus that is the avoidance process target is not the bottleneck apparatus and the substitute feeder that supplies the electronic component that is the avoidance process target is disposed in advance in the extra space 7c shown in FIG. 14.

In FIG. 11, first, it is determined whether the substitute feeder is usable for the electronic component relating to the component shortage simultaneous occurrence (step ST30). That is, it is determined whether the tape feeder 8 that supplies the electronic component relating to the component shortage simultaneous occurrence is disposed in advance in the extra space 7c shown in FIG. 14 with reference to the production data 32. Then, it is determined whether the tact time of the corresponding component mounting apparatus is within the predetermined line tact TL (see FIG. 5B) even if the substitute feeder is used (step ST31). Here, if it is determined in step ST 30 that the substitute feeder is not usable, and if it is determined in step ST 31 that the tact time is not within the predetermined line tact TL, the procedure proceeds to the component shortage simultaneous occurrence avoidance process based on the tact time adjustment for changing a work operation speed and/or a substrate transport timing as a next alternative (step ST34).

Further, if it is determined in step ST 31 that the tact time is within the predetermined line tact TL, the supply of the corresponding electronic component is changed to be performed by the substitute feeder (step ST32). That is, the electronic component is picked up from the tape feeder 8 disposed in the original feeder disposal space 7b, and in addition, the electronic component is also picked up from the substitute feeder 8* disposed in advance in the extra space 7c shown in FIG. 14. Thus, in the tape feeder 8 disposed in the original feeder disposal space 7b, it is possible to reduce the consumption rate of the electronic component, and to thus postpone the component shortage occurrence timing.

In the example shown in FIG. 7, when it is preferable that the component shortage timings (13), (14), and (17) of the component mounting apparatus M3 be postponed (arrows b, c, and e) with respect to the simultaneous occurrence timings t2, t3, and t5 and the component shortage timing (21) of the component mounting apparatus M4 be postponed (arrow f) with respect to the simultaneous occurrence timing t6, the component shortage simultaneous occurrence avoidance process shown in FIG. 11 is selected.

That is, in the component shortage simultaneous occurrence avoidance process shown in FIG. 11, with respect to the component mounting apparatus other than the bottleneck apparatus having the longest cycle time among the plural component mounting apparatuses, by decreasing the consumption rate of the electronic component relating the component shortage occurrence in the component mounting apparatus, the component shortage simultaneous occurrence avoidance process for avoiding the component shortage simultaneous occurrence is executed. Specifically, in the component mounting apparatus that is the simultaneous occurrence avoidance process target, by additionally picking up the electronic component from the substitute feeder 8* that corresponds to the tape feeder 8 that supplies the electronic component relating to the component shortage occurrence and additionally disposed in advance in the extra space 7c of the component supply section 7, the consumption rate of the electronic component in the tape feeder 8 relating to the component shortage occurrence is reduced.

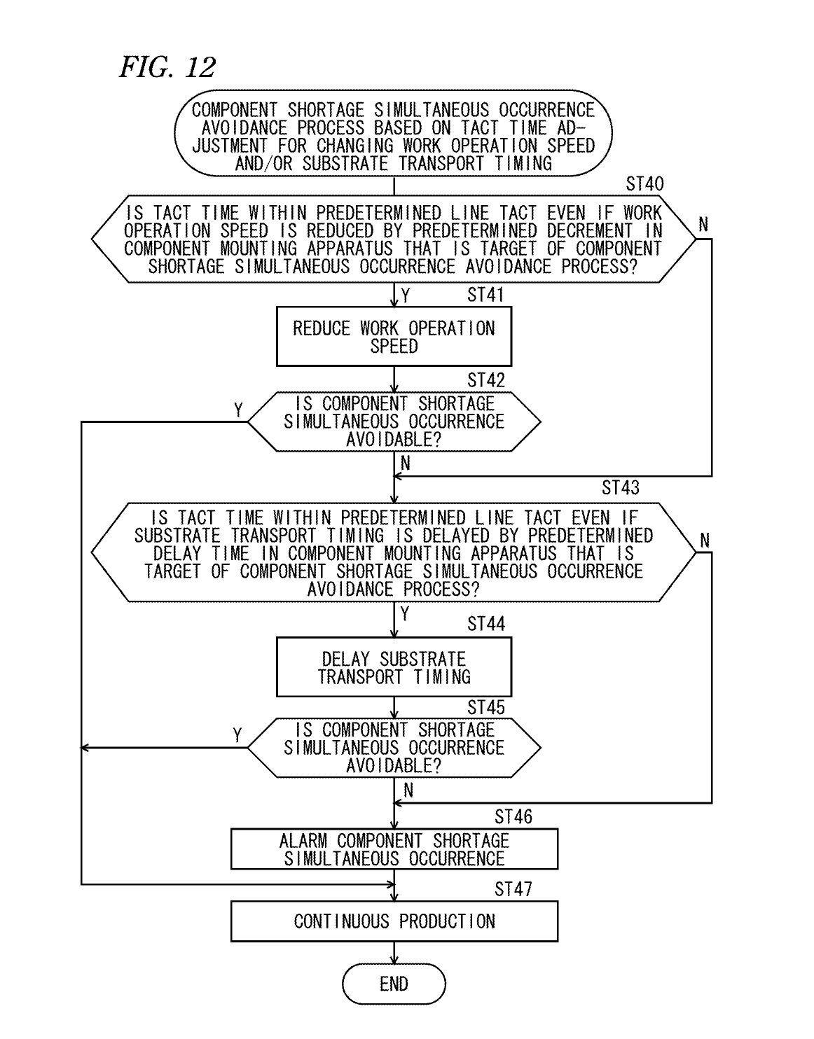

Next, details of the component shortage simultaneous occurrence avoidance process based on the tact time adjustment for changing the work operation speed and/or the substrate transport timing executed in step ST 34 will be described with reference to FIG. 12. This component shortage simultaneous occurrence avoidance process based on the tact time adjustment for changing the work operation speed and/or the substrate transport timing is applied to a case where the component mounting apparatus that is the avoidance process target is not the bottleneck apparatus and the component shortage simultaneous occurrence is not avoidable even through the component shortage simultaneous occurrence avoidance process shown in FIGS. 10 and 11.

In FIG. 12, first, with respect to the component mounting apparatus that is the simultaneous occurrence avoidance process target, it is determined whether the tact time is smaller than or equal to the predetermined line tact TL (see FIG. 5B) even if the work operation speed of the component mounting work is reduced by a predetermined decrement (step ST40). Here, if it is determined that the tact time is equal to or smaller than the line tact TL, a process of reducing the work operation speed by the decrement is performed (step S41). Then, it is determined whether the component shortage simultaneous occurrence is avoidable through this tact time adjustment (step ST42).

Here, if it is determined that the component shortage simultaneous occurrence is avoidable, the procedure proceeds to a continuous production for continuously executing the component mounting work (step ST47). Further, if it is determined in step ST 40 that the tact time is not smaller than or equal to the line tact TL, and if it is determined in step ST 42 that the component shortage simultaneous occurrence is not avoidable, the procedure proceeds to a timing adjustment based on delay of the substrate transport timing as follows.

Here, first, with respect to the component mounting apparatus that is the simultaneous occurrence avoidance process target, it is determined whether the tact time is smaller than or equal to the predetermined line tact TL (see FIG. 5B) even if the substrate transport timing is delayed by a predetermined delay time (step ST43). Here, if it is determined that the tact time is smaller than or equal to the predetermined line tact TL, a process of delaying the substrate transport timing is performed (step ST44). Then, it is determined whether the component shortage simultaneous occurrence is avoidable through this tact time adjustment (step ST45).

Here, if it is determined that the component shortage simultaneous occurrence is avoidable, the procedure proceeds to the continuous production for continuously executing the component mounting work (step ST47). Further, if it is determined in step ST43 that the tact time is not smaller than or equal to the predetermined line tact TL, and if it is determined in step ST45 that the component shortage simultaneous occurrence is not avoidable, the component shortage simultaneous occurrence alarm is given (step ST46), and then, the procedure proceeds to the continuous production (step ST47).

As described above, in the component mounting method according to the present embodiment, during the component mounting work for predicting the component shortage timing when the component replenishment is necessary due to the consumption of the electronic component in each part feeder of the plural component mounting apparatuses and for executing the component replenishment with respect to the corresponding part feeder based on the predicted and notified component shortage timing, it is determined whether the component shortage simultaneous occurrence in which the predicted component shortage timings belong to the same time zone in the plural component mounting apparatuses and the component replenishment is necessary in the same time zone with respect to the plural component mounting apparatuses is present.

Further, if it is determined that the component shortage simultaneous occurrence is present, the component shortage simultaneous occurrence avoidance process is selectively executed according to the characteristics or conditions of the component mounting apparatus, as follows. That is, any one of the method of moving up and the notification of the component shortage timing by the predetermined move-up time to avoid the component shortage simultaneous occurrence, the method of increasing the consumption rate of the electronic component relating to the component shortage occurrence in the component mounting apparatus to avoid the component shortage simultaneous occurrence, and the method of reducing the consumption rate of the electronic component relating to the component shortage occurrence to avoid the component shortage simultaneous occurrence is executed. Thus, it is possible to prevent the apparatus stoppage due to the component shortage simultaneous occurrence in the component mounting system formed by connection of the plural component mounting apparatuses.

In the present embodiment, the tape feeder that pitch-feeds the carrier tape that holds the components is shown as an example of the part feeder, but an application target of the invention is not limited to the tape feeder and may also be applied to other types of component supply devices such as a bulk feeder.

The component mounting method according to the invention has the effect capable of preventing an apparatus stoppage due to component shortage simultaneous occurrence in a component mounting system formed by connection of plural component mounting apparatuses, and is useful in a component mounting field where a component picked up from a part feeder disposed in a component supply section is fed and mounted onto a substrate.

What is claimed is:

1. A component mounting method of performing component mounting work for picking up, in a component mounting system formed by connection of a plurality of component mounting apparatuses that mount an electronic component onto a substrate, the electronic component from a part feeder disposed in a component supply section of each component mounting apparatus and for feeding and mounting the picked-up electronic component onto the substrate, the method comprising:
a component mounting process of executing the component mounting work in the plurality of component mounting apparatuses;
a component shortage prediction process of predicting a component shortage timing when a component replenishment is necessary due to consumption of the electronic component in each part feeder, during the execution of the component mounting work; and
a component replenishment process of executing the component replenishment with respect to the part feeder based on the component shortage timing that is predicted and notified,
wherein it is determined whether a component shortage simultaneous occurrence in which the predicted component shortage timings belong to the same time zone in the plurality of component mounting apparatuses and the component replenishment is necessary in the same time zone with respect to the plurality of component mounting apparatuses is present or not, and
wherein when the component shortage simultaneous occurrence is determined to be present, the component shortage timing is moved up by a predetermined move-up time in any one of the plurality of component mounting apparatuses relating to the component shortage simultaneous occurrence and notified.

2. The component mounting method according to claim 1,
wherein the component mounting apparatus that is a target of the moving up and notification of the component shortage timing is a bottleneck apparatus having the longest cycle time among the plurality of component mounting apparatuses.

3. The component mounting method according to claim 2,
wherein when it is determined that the component shortage simultaneous occurrence is not avoidable even if the move-up time is set to exceed a predetermined upper limit time, an alarm indicating the determination is given.
